(19) United States
(12) Patent Application Publication
(10) Pub. No.: US 2025/0125321 A1
(43) Pub. Date: Apr. 17, 2025

(54) SEMICONDUCTOR PACKAGE

(71) Applicant: SAMSUNG ELECTRONICS CO., LTD., Suwon-si (KR)

(72) Inventors: Junghoon Kang, Suwon-si (KR); Daegon Kim, Suwon-si (KR)

(21) Appl. No.: 18/775,260

(22) Filed: Jul. 17, 2024

(30) Foreign Application Priority Data
Oct. 11, 2023 (KR) 10-2023-0135401

(51) Int. Cl. H01L 25/16; G02B 6/42; G02B 6/43; H01L 23/00; H01L 23/13; H01L 23/31; H01L 23/48; H01L 23/49; H01L 23/538; H01L 27/144

(52) U.S. Cl. CPC H01L 25/167; G02B 6/4245; G02B 6/43; H01L 23/5385; H01L 24/24; H10F 39/10; H01L 23/13; H01L 23/3107; H01L 23/481; H01L 23/49; H01L 24/16; H01L 24/32; H01L 24/33; H01L 2224/16227; H01L 2224/24145; H01L 2224/32145; H01L 2224/33181

(57) ABSTRACT

An example semiconductor package includes a package substrate, an electronic integrated circuit (EIC) package mounted on the package substrate, and a plurality of photonic integrated circuit (PIC) chips stacked on the EIC package. Each PIC chip of the plurality of PIC chips includes an upper groove recessed inwards from an upper surface of the PIC chip and being open toward a first side surface of the PIC chip. The EIC package includes a lower redistribution layer on the package substrate, an EIC chip mounted on the lower redistribution layer, a molding layer surrounding the EIC chip, a through via passing through the molding layer in a vertical direction and electrically connected with the lower redistribution layer, and an upper redistribution layer on the through via.

### CROSS-REFERENCE TO RELATED APPLICATION

This application claims priority under 35 U.S.C. § 119 to Korean Patent Application No. 10-2023-0135401, filed on Oct. 11, 2023, in the Korean Intellectual Property Office, the disclosure of which is incorporated by reference herein in its entirety.

### BACKGROUND

In order to improve the functionality of electronic devices and integrate more components, the advantages of semiconductor package are often taken into consideration. A semiconductor package can be equipped with various integrated circuits such as memory chips or logic chips. In recent years, research on semiconductor packages, including optical integrated circuits, has continued in an environment where data traffic in data centers and communication infrastructure has considerably increased.

### SUMMARY

The present disclosure relates to semiconductor packages, including a semiconductor package allowing a relatively large bandwidth of input/output optical signals and a semiconductor package in which a plurality of photonic integrated circuit chips are stacked in a vertical direction.

The objectives to be solved by the technical spirit of the present disclosure are not limited to the objectives mentioned above, and other objectives can be clearly understood by one of ordinary skill in the art from the following description.

In some implementations, a semiconductor package includes a package substrate, an electronic integrated circuit (EIC) package mounted on the package substrate, and a plurality of photonic integrated circuit (PIC) chips stacked on the EIC package and each including an upper groove recessed inwards from an upper surface and being open toward a first side surface, wherein the EIC package includes a lower redistribution layer arranged on the package substrate, an EIC chip mounted on the lower redistribution layer, a molding layer surrounding the EIC chip, a through via passing through the molding layer in a vertical direction and electrically connected to the lower redistribution layer, and an upper redistribution layer located on the through via.

In some implementations, a semiconductor package includes a package substrate, an electronic integrated circuit (EIC) package mounted on the package substrate, and a plurality of photonic integrated circuit (PIC) chips stacked on the EIC package and each including an upper groove recessed inwards from an upper surface and being open toward a first side surface, wherein the EIC package includes a lower redistribution layer arranged on the package substrate, a connection structure arranged on the lower redistribution layer and including a via structure, an EIC chip mounted on the lower redistribution layer and spaced apart from the connection structure in a horizontal direction, a molding layer located between the connection structure and the EIC chip and covering upper portions of the connection structure and the EIC chip, and an upper redistribution layer arranged on the molding layer and electrically connected to the connection structure.

In some implementations, a semiconductor package includes a main package substrate, a semiconductor chip mounted in a center region of the main package substrate, a sub package substrate mounted in an edge region of the main package substrate and spaced apart from the semiconductor chip in a horizontal direction, an electronic integrated circuit (EIC) package mounted on the package substrate, and a plurality of photonic integrated circuit (PIC) chips stacked on the EIC package and each including an upper groove recessed inwards from an upper surface and being open toward a first side surface, wherein the EIC package includes a lower redistribution layer arranged on the sub package substrate, an EIC chip mounted on the lower redistribution layer, a molding layer surrounding the EIC chip, a through via passing through the molding layer in a vertical direction and electrically connected to the lower redistribution layer, and an upper redistribution layer located on the EIC chip, the molding layer, and the through via.

### BRIEF DESCRIPTION OF THE DRAWINGS

Implementations will be more clearly understood from the following detailed description taken in conjunction with the accompanying drawings.

FIG. 1 is a perspective view schematically illustrating an example of a semiconductor package.

FIG. 2 is an example plan view schematically illustrating the semiconductor package of FIG. 1.

FIG. 3 is an example cross-sectional view taken along a line A-A′ of FIG. 2 and schematically illustrating the semiconductor package of FIG. 2.

FIG. 4 is an example enlarged view of a portion EX1 of FIG. 3 of the semiconductor package of FIG. 3.

FIG. 5 is an example enlarged view of the portion EX1 of FIG. 3 of the semiconductor package.

FIG. 6 is an example enlarged view of the portion EX1 of FIG. 3 of the semiconductor package.

FIG. 7 is an example enlarged view of the portion EX1 of FIG. 3 of the semiconductor package.

FIG. 8 is an example enlarged view of the portion EX1 of FIG. 3 of the semiconductor package.

FIG. 9 is an example enlarged view of the portion EX1 of FIG. 3 of the semiconductor package.

FIG. 10 is a perspective view schematically illustrating an example of a semiconductor package.

FIG. 11 is an example cross-sectional view taken along a line B-B′ of FIG. 9 and schematically illustrating the semiconductor package of FIG. 9.

### DETAILED DESCRIPTION

Since various modifications and various implementations are possible, specific implementations are illustrated in the drawings and described in detail in the detailed description. However, this is not intended to limit these implementations to a specific initiation form.

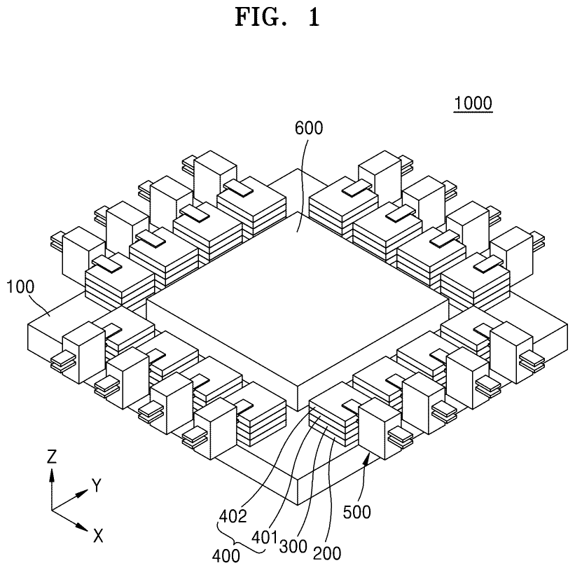

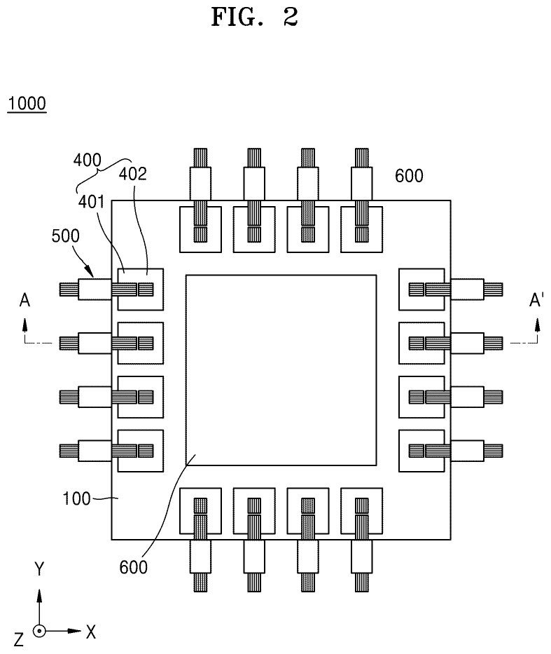

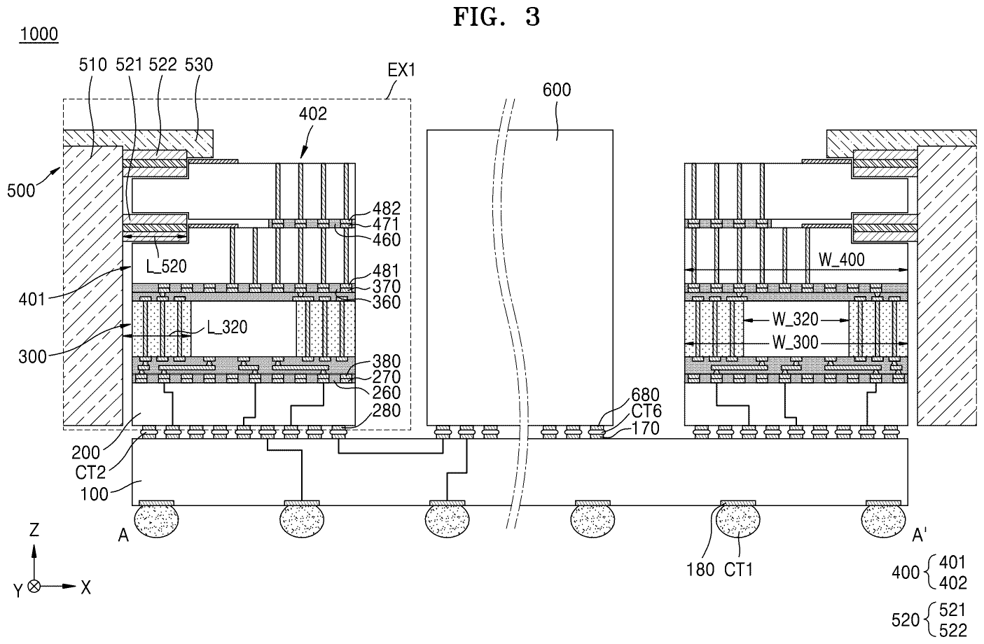

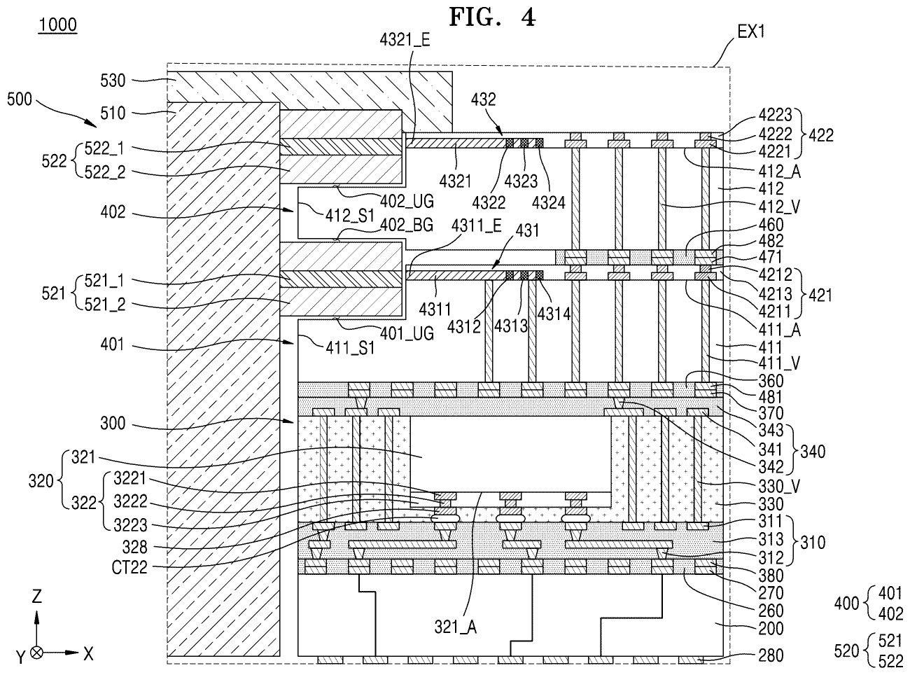

FIG. 1 is a perspective view schematically illustrating an example of a semiconductor package 1000. FIG. 2 is an example plan view schematically illustrating the semiconductor package 1000 of FIG. 1. FIG. 3 is an example cross-sectional view taken along a line A-A′ of FIG. 2 and schematically illustrating the semiconductor package 1000 of FIG. 2. FIG. 4 is an example enlarged view of a portion EX1 of FIG. 3 of the semiconductor package 1000 of FIG. 3.

Referring to FIGS. 1 through 4, the semiconductor package 1000 may include a main package substrate 100, a sub package substrate 200, an electronic integrated circuit package 300, a plurality of photonic integrated circuit chips 400, and a semiconductor chip 600.

Hereinafter, unless specifically defined, a direction that is in parallel to an upper surface of the main package substrate 100 is referred to as a first horizontal direction (X direction), and a direction that is perpendicular to the upper surface of the main package substrate 100 is referred to as a vertical direction (Z direction), and a direction that is perpendicular to the first horizontal direction (X direction) and the vertical direction (Z direction) is referred to as a second horizontal direction (Y direction). A direction in which the first horizontal direction (X direction) and the second horizontal direction (Y direction) are synthesized with each other, is referred to as a horizontal direction.

The main package substrate 100 and the sub package substrate 200 of the semiconductor package 1000 may be, for example, printed circuit boards (PCBs). In some implementations, the main package substrate 100 and the sub package substrate 200 may be referred to as package substrates.

The sub package substrate 200 may be arranged on the main package substrate 100. For example, a plurality of sub package substrates 200 may be mounted on one main package substrate 100. In FIG. 1, four sub package substrates 200 are mounted on each of edges on the upper surface of the main package substrate 100. However, the number of sub package substrates 200 is not limited thereto.

Each of the main package substrate 100 and the sub package substrate 200 may include a core insulating layer including at least one material selected from the group consisting of phenol resin, epoxy resin, and polyimide. For example, the core insulating layer may include at least one material selected from the group consisting of polyimide, frame retardant 4 (FR-4), tetrafunctional epoxy, polyphenylene ether, epoxy/polyphenylene oxide, bismaleimide triazine (BT), thermount, cyanate ester, and liquid crystal polymer.

The main package substrate 100 may include an upper pad 170 located on an upper surface of the core insulating layer and a lower pad 180 located on a lower surface of the core insulating layer. The upper pad 170 and the lower pad 180 may be part of a circuit wiring patterned after a copper (Cu) foil is coated on the upper surface and the lower surface of the core insulating layer. Specifically, the upper pad 170 and the lower pad 180 may be regions that are not covered by a solder resist layer of the circuit wiring and are exposed to the outside.

In some implementations, each of the upper pad 170 and the lower pad 180 may include Cu, nickel (Ni), stainless steel or beryllium copper. An internal wiring for electrically connecting the upper pad 170 to the lower pad 180 may be formed in the main package substrate 100.

External connection terminals CT1 may be attached to the lower pad 180. The external connection terminals CT1 may be configured to connect the main package substrate 100 to an external device on which the main package substrate 100 is mounted, electrically and physically. The external connection terminals CT1 may be formed from solder ball or solder bumps, for example.

The sub package substrate 200 may include an upper pad 270 located on the upper surface of the core insulating layer and a lower pad 280 located on the lower surface of the core insulating layer. The upper pad 270 and the lower pad 280 may be part of a circuit wiring patterned after a Cu foil is coated on the upper surface and the lower surface of the core insulating layer. Specifically, the upper pad 270 and the lower pad 280 may be regions that are not covered by a solder resist layer of the circuit wiring and are exposed to the outside.

In some implementations, each of the upper pad 270 and the lower pad 280 may include Cu, Ni, stainless steel or beryllium copper. An internal wiring for electrically connecting the upper pad 270 to the lower pad 280 may be formed in the sub package substrate 200.

In some implementations, external connection terminals CT2 may be attached to the lower pad 280 of the sub package substrate 200. The external connection terminals CT2 may be configured to connect the sub package substrate 200 to the main package substrate 100 electrically and physically. The external connection terminals CT2 may be formed from solder balls or solder bumps, for example. However, a method of electrically connecting the sub package substrate 200 to the main package substrate 100 is not limited thereto.

In some implementations, the sub package substrate 200 may be mounted on the main package substrate 100 through a socket located on the main package substrate 100. For example, the socket may include at least one of a land grid array (LGA) and a pin grid array (PGA). Through the socket, the sub package substrate 200 may be easily attached/detached to/from the main package substrate 100.

A semiconductor chip 600 of the semiconductor package 1000 may be mounted on the main package substrate 100. The semiconductor chip 600 may be spaced apart from the sub package substrate 200 in the horizontal direction. For example, the semiconductor chip 600 may be located in a center region of the main package substrate 100, and the sub package substrate 200 may be located in an edge region of the main package substrate 100.

The semiconductor chip 600 may include an active surface and an inactive surface facing the active surface. In some implementations, the semiconductor chip 600 may include an application specific integrated circuit (ASIC).

In some implementations, the semiconductor chip 600 may be mounted on the main package substrate 100 so that the active surface faces downwards. In some implementations, the lower pad 680 of the semiconductor chip 600 may be electrically connected to the upper pad 170 of the main package substrate 100 through a connection terminal CT6. However, a method of connecting the semiconductor chip 600 to the main package substrate 100 is not limited thereto.

In some implementations, a variety of a plurality of individual devices may be located on the active surface of the semiconductor chip 600. For example, the plurality of individual devices may include various micro electronic devices, for example, complementary metal-oxide semiconductor (CMOS) transistors, metal-oxide-semiconductor filed effect transistors (MOSFETs), system large scale integration (LSI), image sensors such as CMOS imaging sensors (CISs) or the like, micro-electro-mechanical systems (MEMSs), active devices, passive devices, or the like.

An electronic integrated circuit (EIC) package 300 of the semiconductor package 1000 may be mounted on the sub package substrate 200. For example, the EIC package 300 may be spaced apart from the main package substrate 100 in the vertical direction (Z direction) with the sub package substrate 200 therebetween.

The EIC package 300 may include a lower redistribution layer 310, an EIC chip 320, a molding layer 330, a through via 330_V, and an upper redistribution layer 340.

The lower redistribution layer 310 and the upper redistribution layer 340 of the EIC package 300 may be configured to extend an input/output terminal of the EIC chip 320 to an outer region of the EIC chip 320. For example, at least part of the upper pad 270 of the sub package substrate 200 may be located outside the EIC chip 320 of the EIC package 300. That is, the connection pad 328 of the EIC chip 320 may be electrically connected to the upper pad 270 of the sub package substrate 200 located outside the EIC chip 320 through the lower redistribution layer 310 and/or the upper redistribution layer 340.

The lower redistribution layer 310 of the EIC package 300 may include a lower redistribution line 311, a lower redistribution via 312 for connecting the lower redistribution line 311 vertically, and a lower insulating layer 313 that surrounds the periphery of the lower redistribution line 311 and the lower redistribution via 312. In some implementations, the lower insulating layer 313 may have a shape in which a plurality of layers are stacked.

In some implementations, a first horizontal direction (X direction) width and/or a second horizontal direction (Y direction) width of the lower redistribution via 312 may be gradually increased as getting closer to the EIC chip 320. That is, the horizontal area of the lower redistribution via 312 may be increased as getting adjacent to the EIC chip 320.

The EIC chip 320 of the EIC package 300 may include a first substrate 321 and a first wiring structure 322. The first substrate 321 of the EIC chip 320 may include an active surface 321_A and an inactive surface facing the active surface 321_A. The first wiring structure 322 may be formed on the active surface 321_A of the first substrate 321.

The first substrate 321 may include a semiconductor material such as silicon (Si). Alternatively, the first substrate 321 may include a semiconductor material such as germanium (Ge).

In some implementations, the EIC chip 320 may include a plurality of individual devices through which a plurality of photonic integrated circuit chips 400 interface with other individual devices. The active surface 310_A of the first substrate 321 may be located in the plurality of individual devices of the EIC chip 320. For example, the EIC chip 320 may include CMOS drivers, trans impedance amplifiers, or the like so as to perform functions such as controlling high frequency signaling of each of the plurality of photonic integrated circuit chips 400.

The first wiring structure 322 of the EIC chip 320 may include a first wiring pattern 3221, a first wiring via 3222 connected to the first wiring pattern 3221, and a first insulating layer 3223 that surrounds the first wiring pattern 3221 and the first wiring via 3222. In some implementations, the first wiring structure 322 may have a multi-layered wiring structure including first wiring patterns 3221 and first wiring vias 3222, which are located at different vertical levels.

In some implementations, the EIC chip 320 may be arranged on the lower redistribution layer 310 so that the active surface 321_A of the first substrate 321 faces the lower redistribution layer 310. For example, the EIC chip 320 may have a face down method and may be arranged on the lower redistribution layer 310.

The EIC chip 320 may further include a connection pad 328. The connection pad 328 may be located on a lower surface of the first wiring structure 322 and may be electrically connected to the first wiring via 3222 and/or the first wiring pattern 3221.

The EIC chip 320 may be mounted on the lower redistribution layer 310 by using a chip-last process. For example, when the EIC chip 320 is arranged on the lower redistribution layer 310 by using a face down method, the connection pad 328 of the EIC chip 320 may be electrically connected to the lower redistribution line 311 and/or the lower redistribution via 312 of the lower redistribution layer 310 through the connection terminal CT22.

The EIC chip 320 may be electrically connected to the plurality of photonic integrated circuit chips 400 through the lower redistribution layer 310, the through via 330_V, and the upper redistribution layer 340.

The EIC chip 320 connected to the plurality of photonic integrated circuit chips 400 through the through via 330_V does not include a through via passing through the first substrate 321 so that individual devices may be relatively highly integrated on the active surface 321_A of the first substrate 321.

A molding layer 330 of the EIC package 300 may be located on the lower redistribution layer 310 and formed to surround the EIC chip 320. In some implementations, the molding layer 330 may include epoxy resin, polyimide resin, or the like. The molding layer 330 may include, for example, an epoxy molding compound (EMC).

In some implementations, the molding layer 330 may be formed to expose an upper surface of the EIC chip 320 to the outside. For example, an upper surface of the molding layer 330 may be coplanar with the upper surface of the EIC chip 320.

In some implementations, the horizontal width of the molding layer 330 may be substantially identical to horizontal widths of the lower redistribution layer 310 and the upper redistribution layer 340. For example, the side surface of the molding layer 330, the side surface of the lower redistribution layer 310, and the side of the upper redistribution layer 340 may be substantially located on the same plane.

The through via 330_V of the EIC chip 320 may pass through the molding layer 330. The through via 330_V may pass through the molding layer 330 to electrically connect the lower redistribution layer 310 to the upper redistribution layer 340. For example, the through via 330_V may include a conductive material, for example, Cu, aluminum (Al), silver (Ag), tin (Sn), gold (Au), nickel (Ni), lead (Pb), titanium (Ti), or an alloy thereof.

The upper redistribution layer 340 of the EIC package 300 may be located on the EIC chip 320, the molding layer 330, and the through via 330_V.

The upper redistribution layer 340 may include an upper redistribution line 341, an upper redistribution via 342 connecting the upper redistribution line 341 vertically, and an upper insulating layer 343 that surrounds the periphery of the upper redistribution line 341 to the upper redistribution via 342.

The upper redistribution line 341 and/or the upper redistribution via 342 of the upper redistribution layer 340 may be electrically connected to the through via 330_V. In some implementations, the upper insulating layer 343 may have a shape in which a plurality of layers are stacked.

In some implementations, the area of the upper surface of the EIC chip 320 may be different from the area of the upper surface of the upper redistribution layer 340 and the area of the upper surface of the lower redistribution layer 310. For example, the area of the upper surface of the EIC chip 320 may be less than the area of the upper surface of the upper redistribution layer 340 and the area of the upper surface of the lower redistribution layer 310.

In some implementations, the sum of the area of the upper surface of the EIC chip 320 and the area of the upper surface of the molding layer 330 may be identical to as the area of the upper surface of the upper redistribution layer 340 and the area of the upper surface of the lower redistribution layer 310.

In some implementations, the lower insulating layer 313 and the upper insulating layer 343 may include a photo image-able dielectric (PID), an ajinomoto build-up film (ABF), a solder resist (SR), an epoxy molding compound (EMC), FR-4, and bismaleimide triazine (BT).

In some implementations, materials for the lower insulating layer 313 and the upper insulating layer 343 may be different from each other. For example, the lower insulating layer 313 may include a PID, and the upper insulating layer 343 may include an ABF.

In some implementations, the first horizontal direction (X direction) width and/or the second horizontal direction (Y direction) width of the upper redistribution via 342 may be gradually decreased as getting closer to the EIC chip 320. That is, the horizontal area of the lower redistribution via 312 may be decreased as getting adjacent to the EIC chip 320.

In some implementations, the lower redistribution via 312 and the upper redistribution via 342 may be fully charged with conductive materials, or may have a shape in which the conductive materials are formed along the wall of a via.

The lower redistribution line 311, the lower redistribution via 312, the upper redistribution line 341, and the upper redistribution via 342 may include metal such as Cu, Al, tungsten (W), Ti, tantalum (Ta), indium (In), molybdenum (Mo), manganese (Mn), cobalt (Co), tin (Sn), Ni, magnesium (Mg), rhenium (Re), beryllium (Be), gallium (Ga), ruthenium (Ru), or an alloy of metal, and implementations are not limited thereto.

In some implementations, unlike in FIG. 4, the EIC chip 320 may be arranged on the lower redistribution layer 310 so that the active surface 321_A of the first substrate 321 faces the upper redistribution layer 340. For example, the EIC chip 320 may have a face up method and may be arranged on the lower redistribution layer 310.

In this case, the EIC chip 320 may be electrically connected to the upper redistribution layer 340 through a connection terminal CT22. The EIC chip 320 may be electrically connected to the sub package substrate 200 through the upper redistribution layer 340, the through via 330_V, and the lower redistribution layer 310.

The EIC package 300 may further include a lower pad 380. The lower pad 380 may be arranged on a lower surface of the lower redistribution layer 310 and may be electrically connected to the lower redistribution via 312 and/or the lower redistribution line 311 of the lower redistribution layer 310.

The EIC package 300 may further include an upper pad 370. The upper pad 370 may be arranged on an upper surface of the upper redistribution layer 340 and may be electrically connected to the upper redistribution via 342 and/or the upper redistribution line 341 of the upper redistribution layer 340.

In some implementations, the lower pad 380 of the EIC package 300 may be electrically connected to the upper pad 270 of the sub package substrate 200 through an anisotropic conductive film (ACF) 260. However, a method of connecting the EIC chip 320 to the sub package substrate 200 is not limited thereto.

A plurality of photonic integrated circuit (PIC) chips 400 of the semiconductor package 1000 may be stacked on the EIC package 300. In some implementations, the plurality of PIC chips 400 may include a first PIC chip 401 and a second PIC chip 402 on the first PIC chip 401. In FIG. 1, two PIC chips are stacked on one EIC package 300. However, the number of PIC chips is not limited thereto.

Each of the plurality PIC chips 400 may input and output optical signals. Specifically, each of the plurality of PIC chips 400 may convert electrical signals into optical signals, may transmit the optical signals to a plurality of optical fibers 520, may convert the optical signals transmitted from the plurality of optical fibers 520 into electrical signals, and may transmit the electrical signals to the EIC chip 320.

In some implementations, the horizontal widths W_400 of the plurality of PIC chips 400 may be identical to each other. For example, the plurality of PIC chips 400 may fully overlap each other in the vertical direction. However, implementations are not limited thereto, and the horizontal widths W_400 of the plurality of PIC chips 400 may be different from each other. In addition, the plurality of PIC chips 400 may be offset stacked.

The first PIC chips 401 may include a second substrate 411, a second wiring structure 421, a first optical-electrical conversion unit 431, and a first through via 411_V.

The second substrate 411 may include a semiconductor material, such as Si. Alternatively, the second substrate 411 may include a semiconductor material such as Ge.

The second substrate 411 may include an active surface 411_A having a plurality of individual devices formed therein and an inactive surface facing the active surface 411_A. The second wiring structure 421 may be formed on the active surface 411_A of the second substrate 411. The first through via 411_V may extend from the inactive surface of the second substrate 411 to the active surface 411_A. In some implementations, the first through via 411_V may be electrically connected to the plurality of individual devices on the second wiring structure 421 and/or the active surface 411_A.

The first PIC chips 401 may be arranged on the EIC chip 320 so that the inactive surface of the second substrate 411 faces the EIC chip 320. For example, the PIC chip 401 may have a face up method and may be arranged on the EIC chip 320.

A first upper groove 401_UG of the first PIC chips 401 may be recessed inwards from a first side surface 411_S1 and an upper surface of the first PIC chips 401. For example, the first upper groove 401_UG may be recessed inwards from the upper surface of the first PIC chips 401, and the inside of the first upper groove 401_UG may be open toward the first side surface 411_S1 of the first PIC chip 401. For example, the bottom surface for defining the first upper groove 401_UG may meet with the first side surface 411_S1 of the first PIC chip 401.

In some implementations, the first upper groove 401_UG may be referred to as a V-groove. When the first upper groove 401_UG is seen from the first side surface 411_S1 of the first PIC chip 401, the cross-section of the first upper groove 401_UG may have a shape in which V-shaped grooves overlap part thereof along the first side surface 411_S1 of the first PIC chip 401. In some implementations, a first optical fiber 521 may be mounted in each of the V-shaped grooves.

A first optical-electrical conversion unit 431 of the first PIC chip 401 may convert optical signals to electrical signals and electrical signals into optical signals. In some implementations, the first optical-electrical conversion unit 431 may include a first waveguide 4311, a photodetector 4312, a laser diode 4313, and a modulator 4314.

While the optical signals are input to the first PIC chip 401, the photodetector 4312 may detect the optical signals input to the first PIC chip 401. The first PIC chips 401 may detect the optical signal through the photodetector 4312 and may convert the optical signals into electrical signals. The electrical signals converted by the photodetector 4312 may be transmitted to the plurality of individual devices on the active surface 411_A of the second substrate 411 of the first PIC chip 401.

While the first PIC chip 401 output the optical signals, the plurality of individual devices on the active surface 411_A of the second substrate 411 of the first PIC chip 401 may transmit the electrical signals to the modulator 4314. The modulator 4314 may input signals to light emitted by the laser diode 4313 in response to the electrical signals and may convert the electrical signals into optical signals.

The first waveguide 4311 may be a path through which the optical signals are moved from the first PIC chips 401. The first waveguide 4311 may be a path through which the optical signals transmitted to the first edge coupler 4311_E are moved to the photodetector 4312, or a path through which the optical signals converted by the modulator 4314 are moved to the first edge coupler 4311_E. For example, the optical signals may be moved from the upper surface of the first PIC chip 401 in the horizontal direction along the first waveguide 4311.

The first edge coupler 4311_E may be part of the first waveguide 4311. For example, the first edge coupler 4311_E may be a region onto which the optical signals emitted from the first optical fiber 521 of the first waveguide 4311 are incident. The first edge coupler 4311_E may be a region to which the optical signals are emitted from the first waveguide 4311.

In some implementations, the first waveguide 4311 may be arranged so that the first edge coupler 4311_E may face the first upper groove 401_UG. That is, the first edge coupler 4311_E may be located at an end adjacent to the first upper groove 401_UG of the end of the first waveguide 4311.

In some implementations, the first edge coupler 4311_E may have different horizontal widths from another region of the first waveguide 4311. That is, the first edge coupler 4311_E may have different horizontal widths from another region of the first waveguide 4311 for the transmitting/receiving accuracy of the optical signals. For example, the first edge coupler 4311_E may have a horizontal width that is decreased as getting closer to the first optical fiber 521.

In some implementations, the first edge coupler 4311_E may have a constant length, i.e., a constant thickness in the vertical direction (Z direction). For example, the first edge coupler 4311_E may have a constant thickness in all regions, unlike in a grating coupler. That is, the thickness of the first edge coupler 4311_E may be identical to the thickness of another region of the first waveguide 4311.

In some implementations, the first optical-electrical conversion unit 431 may include a plurality of first edge couplers 4311_E. For example, the first edge couplers 4311_E may one-to-one correspond to the first optical fiber 521. For example, when the optical fiber unit 500 includes a plurality of first optical fibers 521, the plurality of first optical fibers 521 may face the first edge couplers 4311_E that are different from the plurality of first optical fibers 521. That is, the first optical fiber 521 may input/output optical signals to one corresponding first edge coupler 4311_E among the plurality of edge couplers.

In FIG. 4, the first optical-electrical conversion unit 431 is buried in the second insulating layer 4213. However, implementations are not limited thereto, and the first optical-electrical conversion unit 431 may be covered by an oxide layer distinguished from the second insulating layer 4213. That is, an oxide layer may be formed at one side of the second insulating layer 4213, and the first optical-electrical conversion unit 431 may be located inside the oxide layer.

The second wiring structure 421 of the first PIC chip 401 may include a second wiring pattern 4211, a second wiring via 4212 connected to the second wiring pattern 4211, and a second insulating layer 4213 that surrounds the second wiring pattern 4211 and the second wiring via 4212. In some implementations, the second wiring structure 421 may have a multi-layered wiring structure including second wiring patterns 4211 and second wiring vias 4212, which are located at different vertical levels.

In some implementations, the first PIC chip 401 may further include a lower pad 481. The lower pad 481 may be arranged on the lower surface of the first PIC chip 401 and may be electrically connected to the first through via 411_V.

In some implementations, the lower pad 481 of the first PIC chip 401 may be electrically connected to the upper pad 370 of the EIC package 300 through an adhesive film 360. For example, the adhesive film 460 may be an anisotropic conductive film, or a non-conductive film.

However, implementations are not limited thereto, and the first PIC chip 401 and the EIC package 300 may be electrically connected to each other through solder ball attachment, direct bonding, or Cu—Cu hybrid bonding. At this time, a sealing material, such as underfill, may be located between the first PIC chip 401 and the EIC chip 320.

In some implementations, the first PIC chip 401 may further include an upper pad 471. The upper pad 471 may be arranged on an upper surface of the second wiring structure 421 of the first PIC chip 401 and may be electrically connected to the second wiring pattern 4211 and/or the second wiring via 4212.

The second PIC chip 402 may be mounted on the first PIC chip 401. In some implementations, the second PIC chip 402 may include a third substrate 412, a second through via 412_V, a third wiring structure 422, and a second optical-electrical conversion unit 432. In some implementations, the second PIC chip 402 may have substantially the same configuration as that of the first PIC chips 401.

The third substrate 412 of the second PIC chips 402 may include a semiconductor material such as Si. Alternatively, the third substrate 412 may include a semiconductor material such as Ge.

The third substrate 412 may include an active surface 412_A having a plurality of individual devices formed therein and an inactive surface facing the active surface 412_A. The second through via 412_V may extend from the inactive surface to the active surface 412_A of the third substrate 412. In some implementations, the second through via 412_V may be electrically connected to the plurality of individual devices on the third wiring structure 422 and/or the active surface 412_A.

The second PIC chip 402 may be arranged on the first PIC chip 401 so that the inactive surface of the third substrate 412 faces the first PIC chip 401. For example, the second PIC chip 402 having a face up method may be arranged on the first PIC chip 401.

A second upper groove 402_UG in the second PIC chip 402 may be recessed inwards from a first side surface 412_S1 and an upper surface of the second PIC chip 402. For example, the second upper groove 402_UG may be recessed inwards from the upper surface of the second PIC chip 402, and the inside of the second upper groove 402_UG may be open toward the first side surface 412_S1 of the second PIC chip 402. For example, the bottom surface for defining the second upper groove 402_UG may meet with the first side surface 412_S1 of the second PIC chip 402.

In some implementations, the second upper groove 402_UG may be referred to as a V-groove. When the second upper groove 402_UG is seen from the first side surface 412_S1 of the second PIC chip 402, the cross-section of the second upper groove 402_UG may have a shape in which V-shaped grooves overlap part thereof along the first side surface 412_S1 of the second PIC chip 402. In some implementations, a second optical fiber 522 may be mounted in each of the V-shaped grooves.

In some implementations, the first side surface 411_S1 of the first PIC chip 401 and the first side surface 412_S1 of the second PIC chip 402 may face the outside of the main package substrate 100. For example, the first side surface 411_S1 of the first PIC chip 401 and the first side surface 412_S1 of the second PIC chip 402 may face in the same direction.

In some implementations, the first side surface 411_S1 of the first PIC chip 401 and the first side surface 412_S1 of the second PIC chip 402 may face the frame 510 of the optical fiber unit 500.

In some implementations, the first upper groove 401_UG of the first PIC chips 401 and the second upper groove 402_UG in the second PIC chips 402 may be arranged in the vertical direction (Z direction) in a line. For example, When viewed from the first side surface 411_S1 of the first PIC chips 401, the first upper groove 401_UG and the second upper groove 402_UG may be located in a straight line in the vertical direction (Z direction).

In some implementations, the first upper groove 401_UG of the first PIC chips 401 and the second upper groove 402_UG in the second PIC chips 402 may be arranged to be offset in the vertical direction (Z direction) in a line.

In some implementations, the second PIC chip 402 may further include a second lower groove 402_BG.

A second lower groove 402_BG of the second PIC chips 402 may be recessed inwards from a first side surface 412_S1 and a lower surface of the second PIC chips 402. For example, the second lower groove 402_BG may be recessed inwards from the lower surface of the second PIC chips 402, and the inside of the second lower groove 402_BG may be open toward the first side surface 411_S1 of the second PIC chips 402. For example, the ceiling for defining the second lower groove 402_BG may meet with the first side surface 411_S1 of the second PIC chips 402.

A second lower groove 402_BG in the second PIC chips 402 may be located on an upper part of the first upper groove 401_UG of the first PIC chips 401. For example, the second lower groove 402_BG in the second PIC chips 402 may overlap the first upper groove 401_UG of the first PIC chips 401 in the vertical direction (Z direction). In some implementations, the first upper groove 401_UG and the second upper groove 402_UG may be located in a line in the vertical direction (Z direction).

A second lower groove 402_BG in the second PIC chips 402 may serve as the ceiling of the first upper groove 401_UG of the first PIC chips 401. The first optical fiber 521 of the optical fiber unit 500 may be inserted between the first upper groove 401_UG and the second lower groove 402_BG.

In some implementations, a length at which the second lower groove 402_BG is recessed inwards from the first side surface 412_S1 of the second PIC chips 402, and a length at which the first upper groove 401_UG is recessed inwards from the first side surface 411_S1 of the first PIC chips 401, may be the same.

The second optical-electrical conversion unit 432 of the second PIC chips 402 may convert light signals to electrical signals and electrical signals into light signals. In some implementations, the second optical-electrical conversion unit 432 may include a second waveguide 4321, a photodetector 4322, a laser diode 4323, and a modulator 4324.

A second edge coupler 4321_E may be located at one end of the second waveguide 4321 of the second optical-electrical conversion unit 432, and the photodetector 4322, the laser diode 4323, and the modulator 4324 may be located at the other end of the second waveguide 4321 of the second optical-electrical conversion unit 432.

The second edge coupler 4321_E may be part of the second waveguide 4321. For example, the second edge coupler 4321_E may be a region onto which the optical signals emitted from the second optical fiber 522 of the second waveguide 4321 are incident. The second edge coupler 4321_E may be a region in which the optical signals are emitted from the second waveguide 4321 to the second optical fiber 522.

In some implementations, the second waveguide 4321 may be arranged so that the second edge coupler 4321_E may face the second upper groove 402_UG. That is, the second edge coupler 432_E may be located at an end adjacent to the second upper groove 402_UG in the end of the second waveguide 4321.

In some implementations, the photodetector 4322, the photodiode 4323, and the modulator 4324 of the second optical-electrical conversion unit 432 may be substantially identical to the photodetector 4312, the photodiode 4313, and the modulator 4314 of the first optical-electrical conversion unit 431.

The second optical-electrical conversion unit 432 may be buried in the third insulating layer 4223. The third insulating layer 4223 may protect the second optical-electrical conversion unit 432 from the outside. In some implementations, materials for the third insulating layer 4223 and the second insulating layer 4213 may be the same.

The third wiring structure 422 of the second PIC chip 402 may include a third wiring pattern 4221, a third wiring via 4222 connected to the third wiring pattern 4221, and a third insulating layer 4223 that surrounds the third wiring pattern 4221 and the third wiring via 4222. In some implementations, the third wiring structure 422 may have a multi-layered wiring structure including third wiring patterns 4221 and second wiring vias 4212, which are located at different vertical levels.

In some implementations, the second PIC chip 402 may further include a lower pad 482. The lower pad 482 may be arranged on the lower surface of the second PIC chip 402 and may be electrically connected to the second through via 412_V.

In some implementations, the lower pad 482 of the second PIC chip 402 may be electrically connected to the upper pad 471 of the first PIC chips 401 through an adhesive film 460. For example, the adhesive film 460 may be an anisotropic conductive film, or a non-conductive film.

However, implementations are not limited thereto, and the first PIC chip 401 and the second PIC chip 402 may be electrically connected to each other through solderball attachment, direct bonding, or Cu—Cu hybrid bonding. At this time, a sealing material, such as underfill, may be located between the first PIC chip 401 and the second PIC chip 402.

In some implementations, an upper groove in each of the plurality of PIC chips 400 may not overlap the EIC chip 320 of the EIC package 300 in the vertical direction (Z direction). For example, the first upper groove 401_UG and the second upper groove 402_UG may not overlap the EIC chip 320 in the vertical direction (Z direction).

In other words, a molding layer 330 and a through via 330_V of the EIC package 300 may be located at a lower part of the upper recess of each of the plurality of PIC chips 400, and the EIC chip 320 may not be located at a lower part of the upper recess of each of the plurality of PIC chips 400.

For example, a length at which the upper groove in each of the plurality of PIC chips 400 is recessed inwards from the first side surface of each of the plurality of PIC chips 400, may be less than a distance between the sidewall of the molding layer 330 and the sidewall of the EIC chip 320.

In some implementations, the area of an upper surface of each of the plurality of PIC chips 400 may be greater than the area of an upper surface of the EIC chip 320 of the EIC package 300. For example, the area of the upper surface of each of the plurality of PIC chips 400 may be identical to the area of the upper surface of the EIC package 300.

In some implementations, a horizontal width W_300 of the EIC package 300 may be identical to the horizontal width W_400 of each of the plurality of PIC chips 400. Thus, the horizontal width W_320 of the EIC chip 320 buried in the molding layer 330 may be less than the horizontal width W_400 of each of the plurality of PIC chips 400.

The side surface of the EIC package 300 may be coplanar with the side surface of each of the plurality of PIC chips 400. For example, the EIC package 300 and the plurality of PIC chips 400 have the same horizontal area, and the plurality of PIC chips 400 may fully overlap the EIC package 300 in the vertical direction (Z direction).

An optical fiber unit 500 of the semiconductor package 1000 may be attached to the plurality of PIC chips 400. For example, the plurality of optical fibers 520 of the optical fiber unit 500 may be respectively mounted in grooves in the plurality of PIC chips 400.

The optical fiber unit 500 may include a frame 510, and a plurality of optical fibers 520 that extend from the frame 510 to the plurality of PIC chips 400.

The frame 510 of the optical fiber unit 500 may be located outside the main package substrate 100. For example, the frame 510 may be spaced apart from side surfaces of the main package substrate 100 and the sub package substrate 200 in the horizontal direction.

The plurality of optical fibers 520 may be spaced apart from each other in the vertical direction (Z direction). In some implementations, the plurality of optical fibers 520 may be arranged in a line in the vertical direction (Z direction). In some implementations, the plurality of optical fibers 520 may be arranged to be offset in the vertical direction (Z direction).

In some implementations, the plurality of optical fibers 520 may include a first optical fiber 521 and a second optical fiber 522. The first optical fiber 521 may extend from the frame 510 so that one end of the first optical fiber 521 may be located in the first upper groove 401_UG of the first PIC chips 401, and the second optical fiber 522 may extend from the frame 510 so that one end of the second optical fiber 522 may be located in the second upper groove 402_UG in the second PIC chips 402.

In some implementations, the first optical fiber 521 may face the first edge coupler 4311_E of the first PIC chips 401, and the second optical fiber 522 may face the second edge coupler 4321_E of the second PIC chips 402.

In some implementations, the second optical fiber 522 may be fixed into the second upper groove 402_UG by clamping leads 530. For example, the clamping leads 530 may be in contact with the second optical fiber 522 and may serve as the ceiling of the second upper groove 402_UG.

In some implementations, transparent epoxy may be located between the first optical fiber 521 and the first upper groove 401_UG and between the second optical fiber 522 and the second upper groove 402_UG. For example, the transparent epoxy may transmit optical signals and may fix the position of the first optical fiber 521 and the second optical fiber 522.

The first optical fiber 521 and the second optical fiber 522 may be spaced apart from each other in the vertical direction (Z direction). The first optical fiber 521 may be located between the first PIC chips 401 and the second PIC chips 402, and the second optical fiber 522 may be located at an upper portion of the second PIC chip 402.

The first optical fiber 521 may include a first core layer 521_1 and a first clad layer 521_2 that surrounds the first core layer 521_1, and the second optical fiber 522 may include a second core layer 522_1 and a second clad layer 522_2 that surrounds the second core layer 522_1. The first and second core layers 521_1 and 522_1 may have relatively large refractive indexes, and the first and second clad layers 521_2 and 522_2 may have relatively small refractive indexes. Optical signals incident onto the first and second core layers 521_1 and 522_1 may proceed along the first and second core layers 521_1 and 522_1 having large refractive indexes. The optical signals from the first and second core layers 521_1 and 522_1 to the first and second class layers 521_2 and 522_2) are reflected by a difference in refractive indexes between the first and second core layers 521_1 and 522_1 and the first and second clad layers 521_2 and 522_2 and may proceed along the first and second core layers 521_1 and 522_1.

The first core layer 521_1 of the first optical fiber 521 may have the same vertical level as the vertical level of the first edge coupler 4311_E of the first PIC chips 401. The second core layer 522_1 of the second optical fiber 522 may have the same vertical level as the vertical level of the second edge coupler 4321_E of the second PIC chips 402. In the present specification, the “vertical level” means a distance spaced apart from the surface of the main package substrate 100.

In the present specification, the “extension length of the optical fiber” means a distance from one side surface of the frame 510 to one end located inside a groove in the PIC chip.

In some implementations, the extension length L_520 of each of the plurality of optical fibers 520 may be less than a separation distance L_320 between the EIC chip 320 of the EIC package 300 and the frame 510. For example, the plurality of optical fibers 520 may not overlap the EIC chip 320 in the vertical direction (Z direction).

In some implementations, the extension lengths L_520 of the plurality of optical fibers 520 may be different from each other. For example, the extension lengths L_520 of the plurality of optical fibers 520 may be different from each other according to extension lengths of upper grooves in the plurality of PIC chips 400. In addition, when the plurality of PIC chips 400 are offset stacked, the extension lengths L_520 of the plurality of optical fibers 520 may be different from each other.

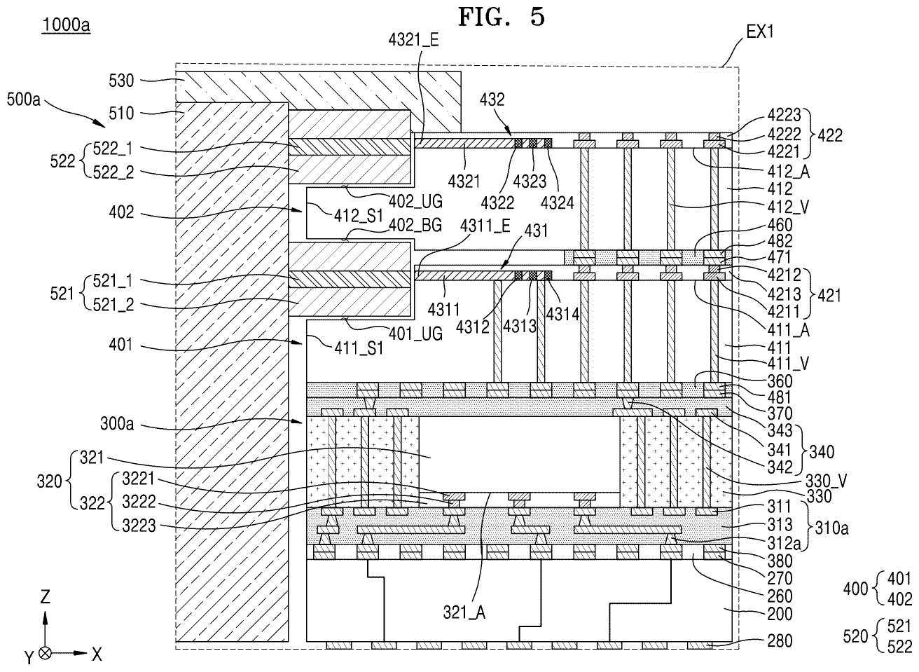

FIG. 5 is an example enlarged view of the portion EX1 of FIG. 3 of a semiconductor package 1000a.

Most components of the semiconductor package 1000a to be described below and materials for forming the components are substantially the same or similar to the previous description in FIG. 1. Thus, for convenience of description, differences between the semiconductor package 1000a of FIG. 5 and the semiconductor package 1000 of FIG. 1 described above will be described.

An EIC package 300a of the semiconductor package 1000a may be formed through a chip first process. Specifically, the EIC package 300a may be manufactured in an order in which the lower redistribution layer 310a is formed after the molding layer 330 and the EIC chip 320 are aligned.

The first wiring structure 322 of the EIC chip 320 may be in direct contact with and electrically connected to the lower redistribution line 311 and/or the lower redistribution via 312a of the lower redistribution layer 310a. For example, through a photolithographic process and an etching process, the lower redistribution layer 310a may be formed on the first wiring structure 322 of the EIC chip 320 so that the EIC chip 320 and the lower redistribution layer 310a may be electrically connected to each other without an additional connection terminal.

In some implementations, the lower surface of the EIC chip 320 and the lower surface of the molding layer 330 may be substantially coplanar. For example, a grinding process may be performed before the lower redistribution layer 310a is formed after the EIC chip 320 and the molding layer 330 are aligned. Thus, the lower surface of the EIC chip 320 and the lower surface of the molding layer 330 may be coplanar.

In some implementations, the first horizontal direction (X direction) width and/or the second horizontal direction (Y direction) width of the lower redistribution via 312a of the lower redistribution layer 310a may be gradually decreased as getting closer to the EIC chip 320. That is, the horizontal area of the lower redistribution via 312a may be decreased as getting adjacent to the EIC chip 320.

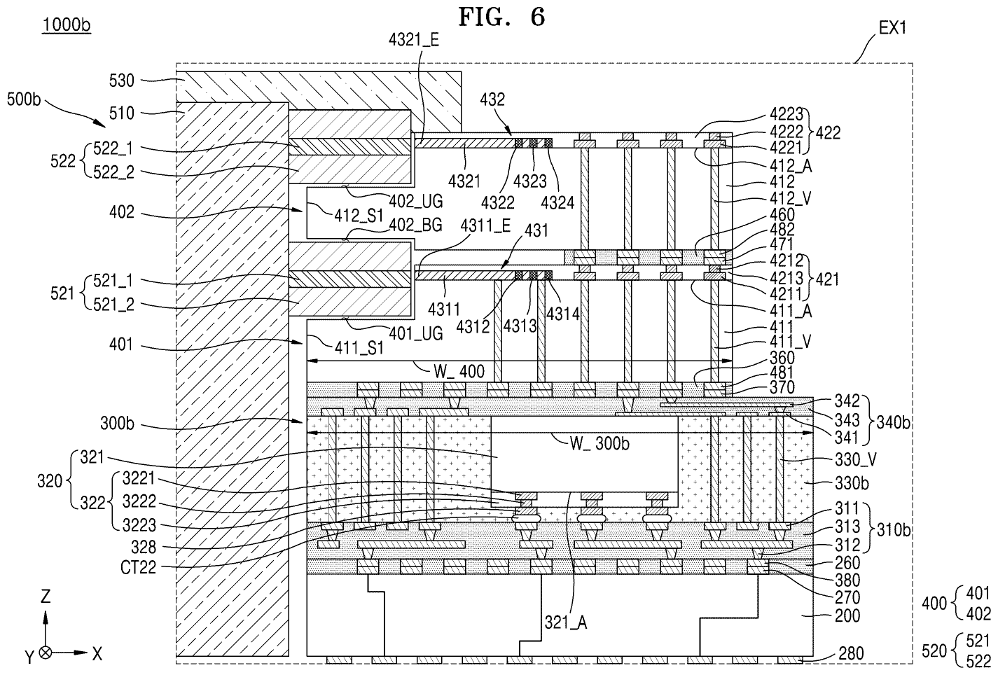

FIG. 6 is an example enlarged view of the portion EX1 of FIG. 3 of a semiconductor package 1000b.

Most components of the semiconductor package 1000b to be described below and materials for forming the components are substantially the same or similar to the previous description in FIG. 1. Thus, for convenience of description, differences between the semiconductor package 1000b of FIG. 6 and the semiconductor package 1000 of FIG. 1 described above will be described.

A horizontal width W_300b of the EIC package 300b of the semiconductor package 1000b and a horizontal width W_400 of each of the plurality of PIC chips 400 may be different from each other.

In some implementations, the horizontal width W_300b of the EIC package 300b may be identical to the horizontal width W_400 of each of the plurality of PIC chips 400. For example, the area of the upper surface of each of the upper redistribution layer 340b and the lower redistribution layer 310b of the EIC package 300b may be greater than the area of the upper surface of each of the plurality of PIC chips 400.

In some implementations, the center of the upper surface of each of the plurality of PIC chips 400 and the center of the upper surface of the EIC package 300b may overlap each other in the vertical direction (Z direction). For example, the center region of the upper surface of the EIC package 300b may be covered by the plurality of PIC chips 400, and other regions may be exposed to the outside.

Owing to the upper redistribution layer 340b and the lower redistribution layer 310b having greater horizontal areas than that of the plurality of PIC chips 400, input/output terminals of the plurality of PIC chips 400 may extend to outer regions of the plurality of PIC chips 400.

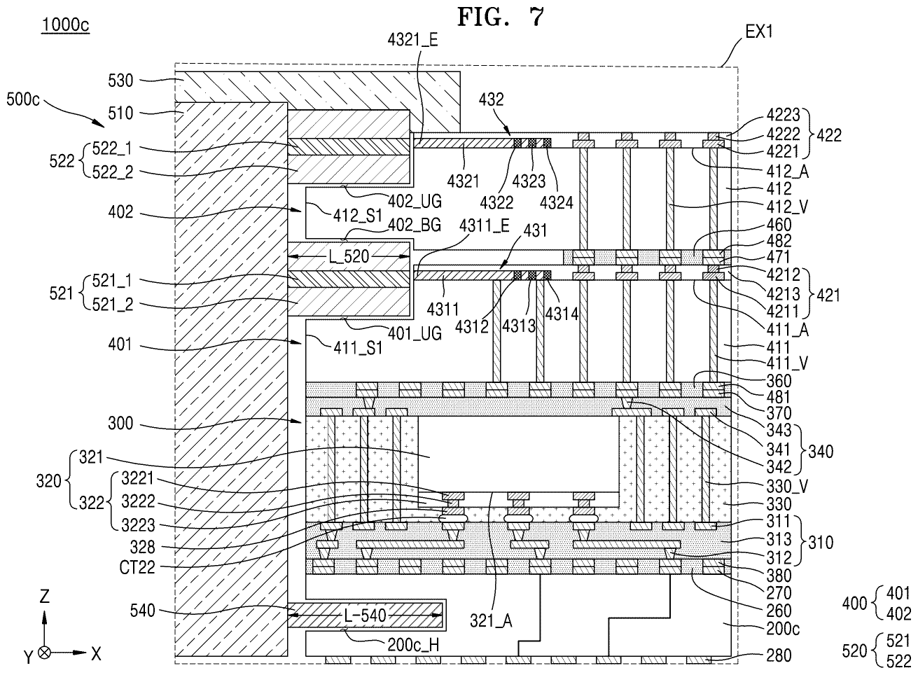

FIG. 7 is an example enlarged view of the portion EX1 of FIG. 3 of a semiconductor package 1000c.

Most components of the semiconductor package 1000c to be described below and materials for forming the components are substantially the same or similar to the previous description in FIG. 1. Thus, for convenience of description, differences between the semiconductor package 1000c of FIG. 7 and the semiconductor package 1000 of FIG. 1 described above will be described.

A sub package substrate 200c of the semiconductor package 1000c may include an alignment hole 200c_H extending from side surfaces inwards. An optical fiber unit 500c of the semiconductor package 1000c may include an alignment pin 540 that protrudes from the frame 510 and is located inside the alignment hole 200c_H.

The shape of the alignment hole 200c_H may correspond to the shape of the alignment pin 540. For example, as the alignment pin 540 gets farther from the frame 510, when the vertical width of the alignment pin 540 is decreased, the vertical width of the alignment hole 200c_H may be decreased as getting farther from the side surface of the sub package substrate 200c. In FIG. 7, the alignment pin 540 and the alignment hole 200c_H are represented by square pillar shapes, but the shapes of the alignment pin 540 and the alignment hole 200c_H are not limited thereto.

In some implementations, the extension length L_540 of the alignment pin 540 may be different from the extension length L_520 of each of the plurality of optical fibers 520. In some implementations, the extension length L_540 of the alignment pin 540 may be different from the extension length L_520 of each of the plurality of optical fibers 520. That is, while the optical fiber unit 500c is coupled to the plurality of PIC chips 400, the alignment pin 540 may be located first in the alignment hole 200c_H of the sub package substrate 200c than the plurality of optical fibers 520 located inside the upper groove.

While the optical fiber unit 500c is coupled to the plurality of PIC chips 400, and while the alignment pin 540 is inserted into the alignment hole 200c_H of the sub package substrate 200c, the optical fiber unit 500c and the plurality of PIC chips 400 may be aligned in advance. Thus, while each of the first optical fiber 521 and the second optical fiber 522 is located in the first upper groove 401_UG and the second upper groove 402_UG, an alignment error of the first optical fiber 521 and the first upper groove 401_UG and an alignment error of the second optical fiber 522 and the second upper groove 402_UG may be relatively reduced.

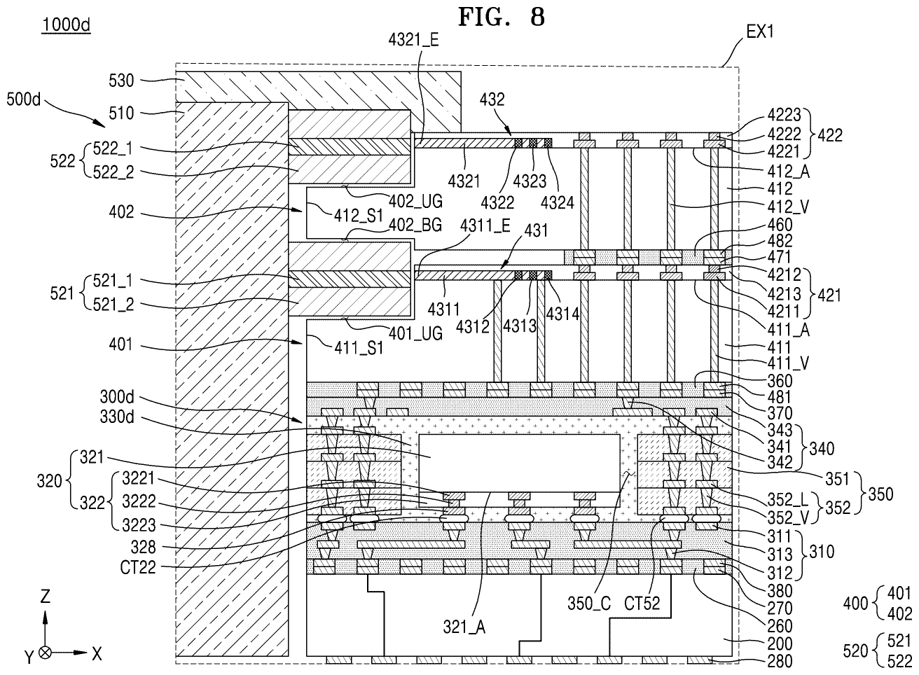

FIG. 8 is an example enlarged view of the portion EX1 of FIG. 3 of a semiconductor package 1000d.

Most components of the semiconductor package 1000d to be described below and materials for forming the components are substantially the same or similar to the previous description in FIG. 1. Thus, for convenience of description, differences between the semiconductor package 1000d of FIG. 8 and the semiconductor package 1000 of FIG. 1 described above will be described.

The EIC package 300d of the semiconductor package 1000d may include a lower redistribution layer 310, an EIC chip 320, a connection structure 350, a molding layer 330d, and an upper redistribution layer 340.

The connection structure 350 of the EIC package 300d may be located on the lower redistribution layer 310 and may include a via structure 352. The connection structure 350 may electrically connect the lower redistribution layer 310 to the upper redistribution layer 340.

The connection structure 350 may include a cavity 350_C that extends from an upper surface to a lower surface of the connection structure 350. The EIC chip 320 may be mounted inside the cavity 350_C of the connection structure 350. For example, the EIC chip 320 may be arranged on the lower redistribution layer 310 and may be spaced apart from the connection structure 350 in the horizontal direction.

The cavity 350_C may be formed in the center of the connection structure 350, as shown in FIG. 1. However, the number of cavities 350_C and arrangement thereof are not limited to the illustration.

The connection structure 350 may include a plurality of base layers 351 and a via structure 352. In some implementations, the plurality of base layers 351 may include first through third base layers stacked in the vertical direction (Z direction). For example, the connection structure 350 may have a multi-layered structure including the first through third base layers. The plurality of base layers 351 may surround at least part of the via structure 352.

In some implementations, each of the plurality of base layers 351 may include an insulating material in which thermosetting resin such as phenol resin, epoxy resin, thermoplastic resin such as polyimide or at least one resin selected therefrom is impregnated with a core including an inorganic filler and/or a glass fiber.

For example, each of the plurality of base layers 351 may include prepreg, ajinomoto build-up film (ABF), frame retardant 4 (FR4), tetrafunctional epoxy, polyphenylene ether, bismaleimide triazine (BT), epoxy/polyphenylene oxide, thermount, cyanate ester, polyimide, liquid crystal polymer, or a combination thereof.

The via structure 352 may include a plurality of connection pads 352_L and a plurality of connection vias 352_V. The plurality of connection pads 352_L may extend from an upper surface or a lower surface of each of the plurality of base layers 351 in the horizontal direction.

In some implementations, the plurality of connection pads 352_L may include first through fourth connection pads located at different vertical levels. For example, first connection pads located at the lowermost end among the plurality of connection pads 352_L may be connected to the lower redistribution layer 310 through a connection terminal CT52. For example, fourth connection pads located at the uppermost end among the plurality of connection pads 352_L may be in direct contact with the upper redistribution via 342 and/or the upper redistribution line 341 and may be connected to the upper redistribution layer 340.

The plurality of connection vias 352_V may extend from the inside of the plurality of base layers 351 in the horizontal direction. The plurality of connection vias 352_V may connect the plurality of connection pads 352_L located at different vertical levels. In some implementations, the plurality of connection vias 352_V may include first through fourth connection vias located at different vertical levels.

In some implementations, each of the plurality of connection pads 352_L may include electrolytically deposited (ED) copper foils, rolled-annealed (RA) copper foils, stainless steel foils, aluminum foils, ultra-thin copper foils, sputtered copper, or copper alloys. In some implementations, the plurality of connection vias 352_V may include Cu, Ni, stainless steel, beryllium copper, or a combination thereof.

A molding layer 330d of the semiconductor package 1000d may be located between the connection structure 350 in the cavity 350_C and the EIC chip 320 and may cover the upper surface of each of the connection structure 350 and the EIC chip 320.

The molding layer 150 may include epoxy-based materials, thermosetting materials, and thermoplastic materials. For example, the molding layer 150 may include ABF, FR-4, BT, EMC, or the like.

The upper redistribution layer 340 may be located on the molding layer 330d. The upper redistribution layer 340 may be electrically connected to the connection structure 350, specifically, the via structure 352. The lower redistribution layer 310 may be electrically connected to the upper redistribution layer 340 through the connection structure 350.

The molding layer 330d may be located between the EIC chip 320 and the upper redistribution layer 340. That is, the EIC chip 320 may be spaced apart from the upper redistribution layer 340 with the molding layer 330d therebetween in the vertical direction (Z direction).

In some implementations, when the active surface 321_A of the first substrate 321 of the EIC chip 320 faces the lower redistribution layer 310, the first wiring structure 322 of the EIC chip 320 may be electrically connected to the plurality of PIC chips 400 through the lower redistribution layer 310, the connection structure 350 and the upper redistribution layer 340.

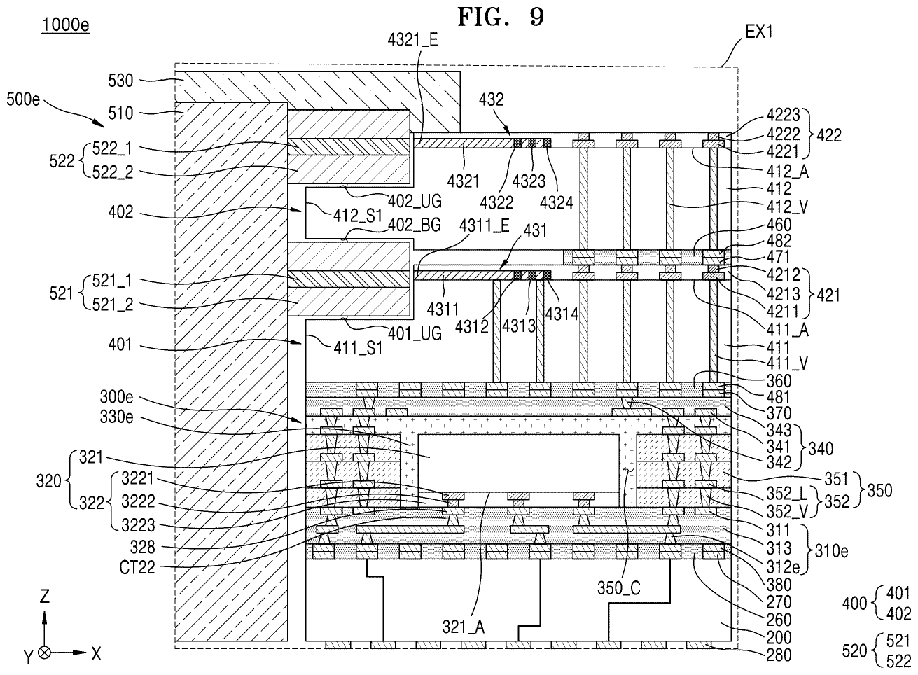

FIG. 9 is an example enlarged view of the portion EX1 of FIG. 3 of a semiconductor package.

Most components of the semiconductor package 1000e to be described below and materials for forming the components are substantially the same or similar to the previous description in FIG. 8. Thus, for convenience of description, differences between the semiconductor package 1000e of FIG. 9 and the semiconductor package 1000d of FIG. 8 described above will be described.

An EIC package 300e of the semiconductor package 1000e may be formed through a chip first process. Specifically, the EIC package 300e may be manufactured in an order in which the lower redistribution layer 310e is formed after the connection structure 350, the molding layer 330e and the EIC chip 320 are aligned.

The first wiring structure 322 of the EIC chip 320 may be electrically connected to the lower redistribution line 311 and/or the lower redistribution via 312e of the lower redistribution layer 310a. For example, the first wiring structure 322 of the EIC chip 320 may be in direct contact with the lower redistribution layer 310e. For example, through a photolithographic process and an etching process, the lower redistribution layer 310e may be formed on the first wiring structure 322 of the EIC chip 320 so that the EIC chip 320 and the lower redistribution layer 310e may be electrically connected to each other without an additional connection terminal.

In some implementations, the EIC chip 320 may be in direct contact with and electrically connected to the lower redistribution layer 310, as in the connection structure 350 and the EIC chip 320.

In some implementations, the lower surface of the EIC chip 320 and the lower surface of the molding layer 330e, and the lower surface of the connection structure 350 may be substantially coplanar. For example, a grinding process may be performed before the lower redistribution layer 310e is formed after the EIC chip 320, the connection structure 350 and the molding layer 330e are aligned. Thus, the lower surface of the EIC chip 320 and the lower surface of the molding layer 330e may be coplanar.

In some implementations, the first horizontal direction (X direction) width and/or the second horizontal direction (Y direction) width of the lower redistribution via 312e of the lower redistribution layer 310e may be gradually decreased as getting closer to the EIC chip 320. That is, the horizontal area of the lower redistribution via 312e may be decreased as getting adjacent to the EIC chip 320.

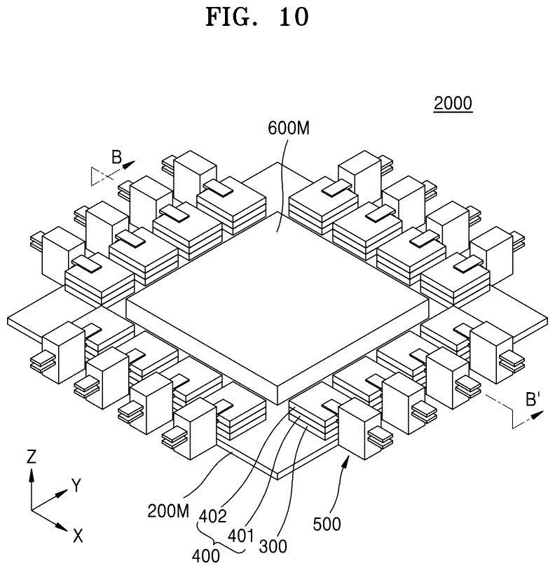

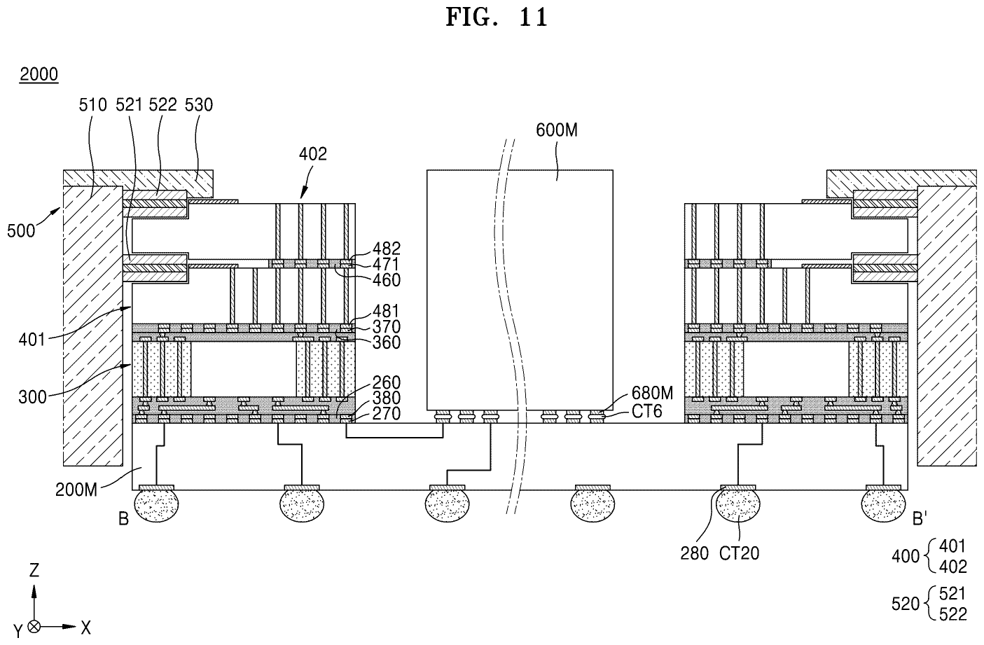

FIG. 10 is a perspective view schematically illustrating an example of a semiconductor package 2000. FIG. 11 is an example cross-sectional view schematically illustrating the semiconductor package 2000 of FIG. 9 taken along a line B-B′ of FIG. 9.

Most components of the semiconductor package 2000 to be described below and materials for forming the components are substantially the same or similar to the previous description in FIG. 1. Thus, for convenience of description, differences between the semiconductor package 2000 of FIG. 10 and the semiconductor package 1000 of FIG. 1 described above will be described.

The semiconductor package 2000 may not include a main package substrate (100 of FIG. 1). A plurality of EIC packages 300 may be mounted on one sub package substrate 200M. For example, the plurality of EIC packages 300 may be arranged along an edge of the upper surface of one sub package substrate 200M. For example, the EIC package 300 and the plurality of PIC chips 400 may be located at an edge region of the sub package substrate 200M.

In FIG. 10, four EIC packages 300 are mounted on each edge of the upper surface of the sub package substrate 200M. However, the number of EIC packages 300 is not limited thereto.

An external connection terminal CT may be attached to the lower pad 280 of the sub package substrate 200M. The external connection terminal CT may be configured to connect the sub package substrate 200M to an external device on which the sub package substrate 200M is mounted, electrically and physically. The external connection terminal CT may be formed from solder balls or solder bumps, for example.

A semiconductor chip 600M may be mounted on the sub package substrate 200M. The semiconductor chip 600M may be spaced apart from the EIC package 300 in the horizontal direction. For example, the semiconductor chip 600M may be located in the center region of the sub package substrate 200M. The lower pad 680M of the semiconductor chip 600M may be electrically connected to the upper pad 270 of the sub package substrate 200M through the connection terminal CT6.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been particularly shown and described with reference to implementations thereof, it will be understood that various changes in form and details may be made therein without departing from the spirit and scope of the following claims.

What is claimed is:

1. A semiconductor package comprising:
a package substrate;
an electronic integrated circuit (EIC) package mounted on the package substrate; and
a plurality of photonic integrated circuit (PIC) chips stacked on the EIC package, each PIC chip of the plurality of PIC chips having an upper surface and a side surface and including an upper groove that is recessed at the upper surface and is open toward the side surface,
wherein the EIC package comprises:
a lower redistribution layer on the package substrate;
an EIC chip mounted on the lower redistribution layer;
a molding layer surrounding the EIC chip;
a through via passing through the molding layer in a vertical direction, the through via being electrically connected with the lower redistribution layer; and
an upper redistribution layer on the EIC chip, the molding layer, and the through via.

2. The semiconductor package of claim 1, wherein the upper groove in each PIC chip of the plurality of PIC chips does not overlap the EIC chip of the EIC package in the vertical direction.

3. The semiconductor package of claim 1, wherein an area of an upper surface of the upper redistribution layer is greater than an area of an upper surface of the EIC chip, and an area of an upper surface of the lower redistribution layer is greater than an area of the upper surface of the EIC chip.

4. The semiconductor package of claim 1, wherein an area of an upper surface of the EIC chip is smaller than an area of the upper surface of each PIC chip of the plurality of PIC chips.

5. The semiconductor package of claim 1, wherein a horizontal width of the EIC package is the same as a horizontal width of each PIC chip of the plurality of PIC chips.

6. The semiconductor package of claim 1, wherein an active surface of the EIC chip faces the lower redistribution layer, and the EIC chip is electrically connected with the plurality of PIC chips through the lower redistribution layer, the through via, and the upper redistribution layer.

7. The semiconductor package of claim 1, wherein the plurality of PIC chips comprises:
a first PIC chip being on the EIC package and defining a first upper groove, and
a second PIC chip being on the first PIC chip and defining a second upper groove and a second lower groove, the second upper groove being recessed inwards from an upper surface of the second PIC chip, and the second lower groove being recessed inwards from a lower surface of the second PIC chip and being open toward a first side surface of the second PIC chip.

8. The semiconductor package of claim 7, wherein the second lower groove in the second PIC chip overlaps the first upper groove in the first PIC chip in the vertical direction.

9. The semiconductor package of claim 7, wherein the first PIC chip comprises a first waveguide at an upper surface of the first PIC chip, the second PIC chip comprises a second waveguide at the upper surface of the second PIC chip, the first waveguide comprises a first edge coupler at an end of the first waveguide adjacent to the first upper groove, and the second waveguide comprises a second edge coupler at an end of the second waveguide adjacent to the second upper groove.

10. The semiconductor package of claim 1, comprising an optical fiber unit including a frame and a plurality of optical fibers extending from the frame,
wherein the plurality of optical fibers are spaced apart from each other in the vertical direction, and the plurality of optical fibers are respectively located at the upper grooves in the plurality of PIC chips.

11. The semiconductor package of claim 10, wherein an extension length of each optical fiber of the plurality of optical fibers is smaller than a separation distance between the EIC chip and the frame of the optical fiber unit.

12. The semiconductor package of claim 10, wherein the package substrate defines an alignment hole at a side surface of the package substrate, and
wherein the optical fiber unit comprises an alignment pin extending from the frame, the alignment pin having one end located at the alignment hole.

13. A semiconductor package comprising:
a package substrate;
an electronic integrated circuit (EIC) package mounted on the package substrate; and
a plurality of photonic integrated circuit (PIC) chips stacked on the EIC package, each PIC chip of the plurality of PIC chips having an upper surface and a side surface and including an upper groove that is recessed at the upper surface and is open toward the side surface,
wherein the EIC package comprises:
a lower redistribution layer on the package substrate;
a connection structure on the lower redistribution layer, the connection structure comprising a via structure;
an EIC chip mounted on the lower redistribution layer, the EIC chip being spaced apart from the connection structure in a horizontal direction;
a molding layer between the connection structure and the EIC chip, the molding layer covering an upper portion of the connection structure and an upper portion of the EIC chip; and
an upper redistribution layer on the molding layer, the upper redistribution layer being electrically connected with the connection structure.

14. The semiconductor package of claim 13, wherein the EIC chip is spaced apart from the upper redistribution layer in a vertical direction, the molding layer being between the EIC chip and the upper redistribution layer.

15. The semiconductor package of claim 13, wherein an active surface of the EIC chip faces the lower redistribution layer, and the EIC chip is electrically connected with the plurality of PIC chips through the lower redistribution layer, the connection structure, and the upper redistribution layer.

16. The semiconductor package of claim 13, wherein at least part of an upper pad of the package substrate is outside the EIC chip.

17. The semiconductor package of claim 13, comprising a semiconductor chip on the package substrate, the semiconductor chip being spaced apart from the EIC chip in the horizontal direction.

18. A semiconductor package comprising:
a main package substrate;
a semiconductor chip mounted in a center region of the main package substrate;
a sub package substrate mounted on an edge region of the main package substrate, the sub package substrate being spaced apart from the semiconductor chip in a horizontal direction;
an electronic integrated circuit (EIC) package mounted on the sub package substrate; and
a plurality of photonic integrated circuit (PIC) chips stacked on the EIC package, each PIC chip of the plurality of PIC chips having an upper surface and a side surface and including an upper groove that is recessed at the upper surface and is open toward the side surface,
wherein the EIC package comprises:
a lower redistribution layer on the sub package substrate;
an EIC chip mounted on the lower redistribution layer;
a molding layer surrounding the EIC chip;
a through via passing through the molding layer in a vertical direction, the through via being electrically connected with the lower redistribution layer; and
an upper redistribution layer on the EIC chip, the molding layer and the through via.

19. The semiconductor package of claim 18, wherein a horizontal width of the EIC package is smaller than a horizontal width of each PIC chip of the plurality of PIC chips.

20. The semiconductor package of claim 18, wherein the upper groove in each PIC chip of the plurality of PIC chips does not overlap the EIC chip in the vertical direction.
